(19) United States
(12) Patent Application Publication
(10) Pub. No.: US 2019/0088751 A1
(43) Pub. Date: Mar. 21, 2019

(54) THIN FILM TRANSISTOR AND MANUFACTURING METHOD THEREFOR, ARRAY SUBSTRATE, AND DISPLAY DEVICE

(71) Applicants: BOE TECHNOLOGY GROUP CO., LTD., Beijing (CN); Chongqing BOE Optoelectronics Technology Co., Ltd., Chongqing (CN)

(72) Inventors: Xiaoyuan WANG, Beijing (CN); Ni YANG, Beijing (CN); Wu WANG, Beijing (CN); Yan FANG, Beijing (CN)

(21) Appl. No.: 15/993,804

(22) Filed: May 31, 2018

(30) Foreign Application Priority Data
Sep. 20, 2017 (CN) 201710854302.9

(51) Int. Cl. H01L 29/417; H01L 27/12; H01L 29/786; H01L 29/66

(52) U.S. Cl. CPC H01L 29/41733; H01L 27/1288; G02F 2201/123; H01L 29/78618; H01L 29/66742; H01L 27/124

(57) ABSTRACT

The disclosure discloses a thin film transistor and a manufacturing method therefor, an array substrate, and a displaying device. The TFT includes a first electrode comprising strip arms and a connecting arm connected with the strip arms, a second electrode comprising a strip arm, an active layer, a gate, and a gate insulation layer. The strip arms are arranged sequentially in a first direction which is perpendicular to the extending direction of the strip arms. The projection of the connecting arm of the first electrode on the gate does not have an overlapped region with the gate. A region between this connecting arm and the strip arms of the second electrode is a first region. The orthogonal projection of the active layer on the first electrode or the second electrode has a portion within the first region which is at least partially hollowed-out.

### CROSS-REFERENCE TO RELATED APPLICATIONS

This application claims the benefit of Chinese Patent Application No. 201710854302.9, filed on Sep. 20, 2017 and entitled “THIN FILM TRANSISTOR AND MANUFACTURING METHOD THEREFOR, ARRAY SUBSTRATE, AND DISPLAYING DEVICE”, and the content of which is incorporated by reference herein in its entirety.

### TECHNICAL FIELD

The present disclosure relates to the field of display technology, and in particular, to a thin film transistor and a manufacturing method therefor, an array substrate, and a displaying device.

### BACKGROUND

Now in both liquid crystal displays (LCDs) and organic light emitting diode (OLED) displays there are provided thin film transistors (TFTs) for controlling display of pixels. Accordingly, the performance of displaying devices is closely related to that of TFTs.

### SUMMARY

The embodiments of the disclosure disclose a thin film transistor and a manufacturing method therefor, an array substrate and a displaying device.

The embodiments of the disclosure disclose the following technical solutions.

In a first aspect, there is provided a thin film transistor comprising a first electrode, a second electrode, an active layer, a gate and a gate insulation layer, wherein the first electrode comprises a strip arm and a connecting arm connected with the strip arm, the second electrode comprises a strip arm, the strip arms are arranged sequentially in a first direction which is perpendicular to the extending direction of the strip arms; and wherein the projection of the connecting arm of the first electrode on the gate does not have an overlapped region with the gate, and a portion of an orthogonal projection of the active layer on the first electrode or the second electrode within a first region, which is a region between the connecting arm and the strip arm of the second electrode, is at least partially hollowed-out.

In one embodiment, the first electrode comprises two said trip arms and one said connecting arm, wherein the connecting arm is connected with ends of the two strip arms to form a U-shaped structure, and wherein the second electrode comprises one said strip arm which is positioned within an opening of the U-shaped structure.

In one embodiment, the first electrode comprises one said connecting arm and one said trip arm, wherein the connecting arm and the strip arm are connected with one another to form a L-shaped structure, and wherein the second electrode comprises one said strip arm which is positioned within an opening of the L-shaped structure.

In one embodiment, the number of the strip arm of the second electrode is less than that of the strip arm of the first electrode, and wherein the second electrode is an electrode for inputting signals.

In a second aspect, there is provided an array substrate comprising a plurality of aforesaid thin film transistors.

In one embodiment, the first electrode of the thin film transistor is electrically connected with a pixel electrode through a via, and the second electrode is electrically connected with a data line; or the second electrode of the thin film transistor is electrically connected with a pixel electrode through a via, and the first electrode is electrically connected with a data line.

In a third aspect, there is provided a thin film transistor comprising a first electrode, a second electrode, an active layer, a gate and a gate insulation layer, wherein the first electrode comprises a strip arm and a connecting arm connected with the strip arm, the second electrode comprises a strip arm, the strip arms are arranged sequentially in a first direction which is perpendicular to the extending direction of the strip arms; and wherein the number of the strip arm of the second electrode is less than that of the strip arm of the first electrode or the second electrode does not comprise the connecting arm, wherein the second electrode is an electrode for inputting signals.

In one embodiment, the projection of the connecting arm of the first electrode on the gate does not have an overlapped region with the gate, and a portion of an orthogonal projection of the active layer on the first electrode or the second electrode within a first region, which is a region between the connecting arm and the strip arm of the second electrode, is at least partially hollowed-out.

In one embodiment, the first electrode comprises two said trip arms and one said connecting arm, wherein the connecting arm is connected with ends of the two strip arms to form a U-shaped structure, and wherein the second electrode comprises one said strip arm which is positioned within an opening of the U-shaped structure.

In a fourth aspect, there is provided an array substrate comprising a plurality of aforesaid thin film transistors.

In one embodiment, the first electrode of the thin film transistor is electrically connected with a pixel electrode through a via, and the second electrode is electrically connected with a data line.

In a fifth aspect, there is provided a displaying device comprising an aforesaid array substrate.

In a sixth aspect, there is provided a method for preparing a thin film transistor comprising: forming, on a base substrate, a gate, a gate insulation layer, an active layer, a first electrode and a second electrode, wherein the first electrode comprises a strip arm and a connecting arm connected with the strip arm, the second electrode comprises a strip arm, the strip arms are arranged sequentially in a first direction which is perpendicular to the extending direction of the strip arms, and wherein the projection of the connecting arm of the first electrode on the gate does not have an overlapped region with the gate, and a portion of the active layer directly opposite a first region, which is a region between the connecting arm and the strip arm of the second electrode, is at least partially hollowed-out.

In one embodiment, forming on a base substrate an active layer, a first electrode and a second electrode comprises: forming a thin film for active layer on the base substrate, forming a conductive thin film on the thin film for active layer, using a half-tone mask to simultaneously mask and expose the thin film for active layer and the conductive thin film, and using one etching process to form the active layer, the first electrode and the second electrode.

In a seventh aspect, there is provided a method for preparing a thin film transistor comprising: forming, on a base substrate, a gate, a gate insulation layer, an active layer, a first electrode and a second electrode, wherein the first electrode comprises a strip arm and a connecting arm connected with the strip arm, the second electrode comprises a strip arm, the strip arms are arranged sequentially in a first direction which is perpendicular to the extending direction of the strip arms, wherein the number of the strip arm of the second electrode is less than that of the strip arm of the first electrode or the second electrode does not comprise the connecting arm, and wherein the second electrode is an electrode for inputting signals.

### BRIEF DESCRIPTION OF THE DRAWINGS

Now brief description of the drawings for describing embodiments or prior art of the disclosure will be made in order to explain more clearly the technical solutions of the embodiments or prior art. Apparently, the drawings in the following description only involve some embodiments of the disclosure, and it will be apparent to those skilled in the art that other drawings will be gained from therefrom without creative efforts.

FIG. 1 is a schematic structural view of a TFT according to prior art.

FIG. 2(a) is a schematic structural view of a TFT according to a first embodiment of the disclosure.

FIG. 2(b) is a schematic cross view in the direction of BB′ shown in FIG. 2(a).

FIG. 3(a) is a schematic structural view of a TFT according to a second embodiment of the disclosure.

FIG. 3(b) is a schematic cross view in the direction of CC′ shown in FIG. 3(a).

FIG. 3(c) is a schematic cross view in the direction of AA′ shown in FIG. 3(a)

FIG. 4 is a schematic structural view of a TFT according to a third embodiment of the disclosure.

FIG. 5 is a schematic view for comparing gate parasitic capacitance of a TFT according to an embodiment of the disclosure and prior art.

FIG. 6 is a schematic view for comparing drain and gate parasitic capacitance of a TFT according to an embodiment of the disclosure and prior art.

FIG. 7 is a schematic view for comparing source and gate parasitic capacitance of a TFT according to an embodiment of the disclosure and prior art.

FIG. 8 is a schematic structural view of a TFT according to a fourth embodiment of the disclosure.

FIG. 9 is a schematic structural view of a TFT according to a fifth embodiment of the disclosure.

### LIST OF NUMERAL REFERENCES

10 first electrode
100 strip arm
20 second electrode
200 connecting arm
30 active layer
40 channel
50 gate
60 via
70 data line
80 base board for substrate
90 gate insulation layer
110 pixel electrode

### DETAILED DESCRIPTION

Hereinafter, the technical solutions of the embodiments of the disclosure will be described clearly and completely with reference to the accompanying drawings of the embodiments of the disclosure. It is obvious that the described embodiments are only part but not all of the embodiments of the present disclosure. All other embodiments obtained by those skilled in the art based on the described embodiments of the disclosure without creative efforts are within the protection scope of the disclosure.

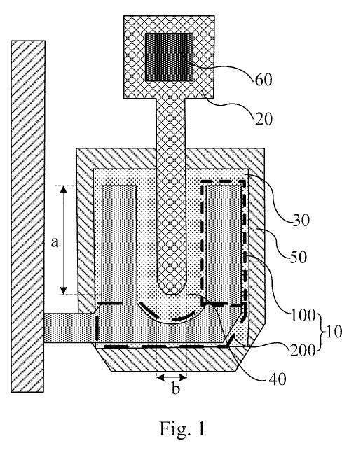

In order to ensure high resolution and smooth change in displayed images of the displaying devices, the TFTs have relatively short time for charging in off-state. Insufficient charging for capacitors of pixels in short time is a big problem influencing the displaying quality of displaying devices, in particular for products of gate driver on array (GOA) due to short time for charging and limited driving capability of GOA. Conventionally, charging rate is usually improved by increasing the ratio of width to length (W/L) of TFTs, for example increasing the width of channels W to increase on-state current Ion. Exemplarily, referring to FIG. 1, a TFT of U-shaped structure has a first electrode 10 which comprises two strip arms 100 and a connecting arm 200 connecting ends of the two strip arms 100. Between the first electrode 10 and a second electrode 20 there is an active layer 30 forming a channel 40 of U-shaped structure. At present time, W/L is usually increased by increasing the length of free ends of the striped-shaped arms 100, i.e., the width of the channel W.

However, increasing the width of channel W may reduce pixel aperture ratio of pixels, thereby influencing transmission ratio of displaying panels and increasing power loss of backlight.

It is known from the capacitance formula C=ε·S/d, where ε is the dielectric constant, S is overlapped area and d is the thickness of dielectric, that the size of the capacitance is directly proportional to the overlapped area of two electrodes in the case where the size of ε and d is kept constant. In embodiments of the disclosure the capacitance is indicated by the overlapped area.

The parasitic capacitance of the displaying panel comprises gate line parasitic capacitance Cg and data line parasitic capacitance Cd. Typically, the overlapped capacitance arising from the overlapped area is substituted for the parasitic capacitance.

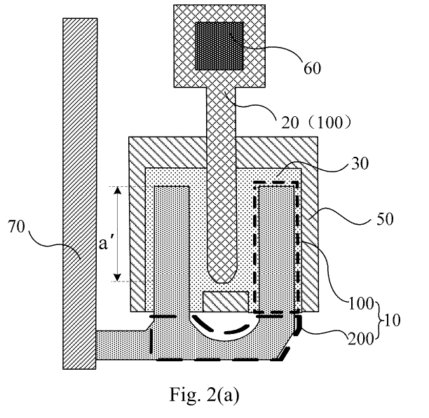

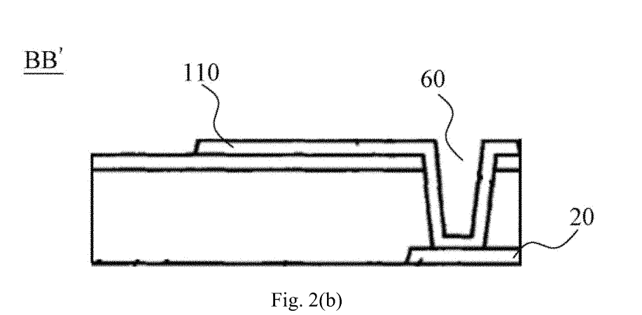

A TFT according to an embodiment of the disclosure, as shown in FIG. 2(a), comprises a first electrode 10 comprising a strip arm 100 and a connecting arm 200 connected with the strip arm 100, a second electrode 20 comprising a strip arm 100, an active layer 30, a gate 50, and a gate insulation layer (not shown in the figure of the present embodiment). The strip arms 100 are arranged sequentially in a first direction which is perpendicular to the extending direction of the strip arms 100. The connecting arm 200 of the first electrode 10 has a projection on the gate 50 which does not have an overlapped region with the gate 50. A region between this connecting arm 200 and the strip arms 100 of the second electrode 20 is a first region. The orthogonal projection of the active layer 30 on the first electrode 10 or the second electrode 20 has a portion within the first region which is at least partially hollowed-out.

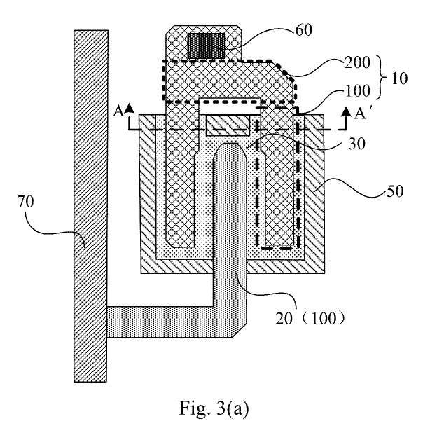

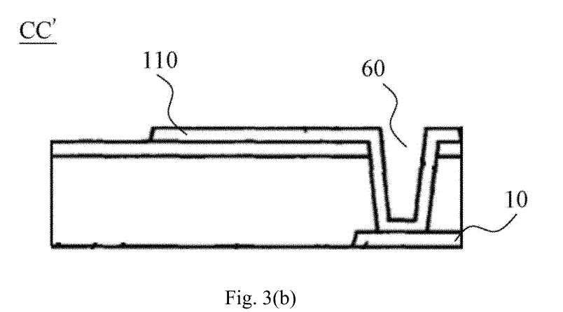

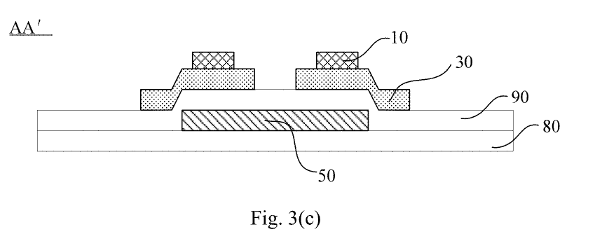

It should be noted that firstly, for the first and second electrode 10 and 20 of the TFT, as shown in FIG. 2(a) and FIG. 2(b), the first electrode 10 of the TFT may be connected with the data line 70, and the second electrode 20 may be connected through a via 60 with a pixel electrode 110. Alternatively, as shown in FIG. 3(a) and FIG. 3(b), the first electrode 10 may be connected with the pixel electrode 110 through the via 60 and the second electrode 20 may be connected with the data line 70.

Here, whether the first or second electrode 10 or 20 is the source or drain in particular is related to the flowing direction of current. When in the TFT the current is input from the first electrode 10 to the second electrode 20, the first electrode 10 is the source and the second electrode 20 is the drain; when the current is input from the second electrode 20 to the first electrode 10, the second electrode 20 is the source and the first electrode 10 is the drain. Exemplarily, the first electrode 10 is connected with the data line 70 and the second electrode 20 is connected with the pixel electrode 110. When the TFT is charged, the current flows from the first electrode 10 to the second electrode 20 with the first electrode 10 as the source and the second electrode 20 as the drain. When the TFT is discharged, the current flows from the second electrode 20 to the first electrode 20 with the second electrode 20 as the source and the first electrode 20 as the drain.

Secondly, the sequential arrangement of the strip arms 100 in the first direction refers to the sequential arrangement of all of the strip arms 100 in the first direction, i.e., the trip arm 100 of the first electrode 10 and the strip arm 100 of the second electrode 20 are all arranged sequentially in the first direction.

Portions of the first and second electrode 10 and 20 connected with the data line 70 and the pixel electrode 110 are connecting electrodes, which are neither the trip arms 100 nor the connecting arm 200. Based thereon, except the connecting electrodes, portions of the first and second electrode 10 and 20 which intersect with the extension of the strip arms 100 are connecting arms 200.

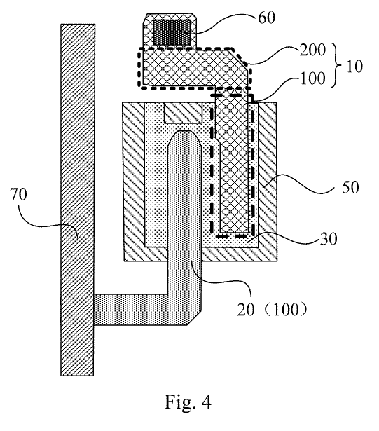

Thirdly, there is no limitation to the number of the strip arm 100 and the number of the connecting arm 200 included by the first electrode 10. For example, as shown in FIGS. 2 and 3(a), the first electrode 10 comprises two strip arms 100 and one connecting arm 200 which is connected with two ends of the strip arms. Alternatively, as shown in FIG. 4, the first electrode 10 comprises one strip arm 100 and one connecting arm 200.

The second electrode 20 comprises a connecting arm 200 (not shown in the Fig. of the embodiment) besides the strip arm 100, in which case there is no limitation to the number of the strip arm 100 included by the second electrode 20, which may be set on demand.

Fourthly, the portion of the orthogonal projection of the active layer 30 on the first electrode 10 or the second electrode 20 which is within the first region is at least partially hollowed-out. Alternatively, the portion of the active layer 30 in the first region is completely hollowed-out. Alternatively, the portion of the active layer 30 in the first region is partially hollowed-out.

Fifthly, for simplicity of describing the embodiments of the disclosure, hereinafter, the electrode connected with the data line 70 is referred to as the drain while the electrode connected with the pixel electrode 110 is referred to as the source.

The gate line parasitic capacitance Cg mainly comprises source and gate parasitic capacitance Cgs, and drain and gate parasitic capacitance Cgd. Since the active layer is in switched-on state when the gate line is opened, the gate line parasitic capacitance Cg may be considered as the parasitic capacitance Cg of the TFT at the active layer 30 and the gate line.

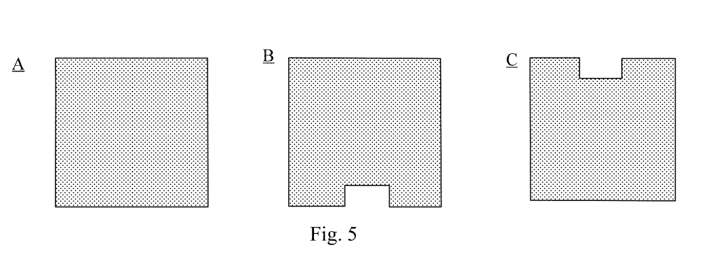

Since the region between the connecting arm 200 of the first electrode 10 and the strip arms 100 of the second electrode 20 is the first region, and the portion of the active layer 30 directly opposite the first region is partially hollowed-out, the overlapped area of the active layer 30 and the gate according to the embodiments of the disclosure is reduced in comparison with the prior art, that is to say, the gate line parasitic capacitance Cg is reduced. In particular, referring to FIG. 5, when the gate line is opened, the gate line parasitic capacitance Cg of the TFT in the prior art as shown in FIG. 1 is shown in FIG. 5A, the gate line parasitic capacitance Cg of the TFT according to the embodiment of the disclosure as shown in FIG. 1 is shown in FIG. 5B, and the gate line parasitic capacitance Cg of the TFT according to the embodiment of the disclosure as shown in FIG. 3(a) is shown in FIG. 5C. It can be seen from FIG. 5 that the area shown in FIG. 5A is greater than either that of the area shown in FIG. 5B or that in FIG. 5C. Based thereon, the gate line parasitic capacitance Cg according to the embodiments of the disclosure is reduced in comparison with the prior art.

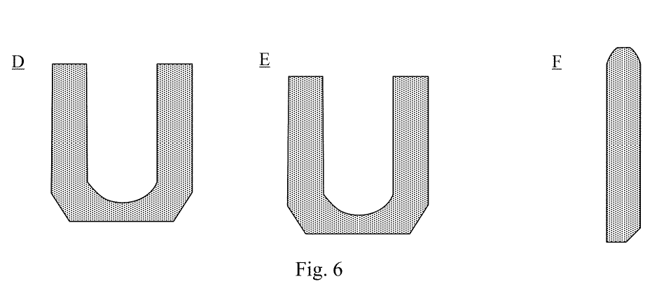

The data line parasitic capacitance Cd is the drain and gate parasitic capacitance Cdg when the TFT is in the switched-off state. Referring to FIG. 6, the data line parasitic capacitance Cdg of the TFT in the prior art as shown in FIG. 1 is shown in FIG. 6D, the data line parasitic capacitance Cdg of the TFT according to the embodiment of the disclosure as shown in FIG. 2(a) is shown in FIG. 6E, and the data line parasitic capacitance Cdg of the TFT according to the embodiment of the disclosure as shown in FIG. 3(a) is shown in FIG. 6F. It can be seen from FIG. 6 that the area shown in FIG. 6D is substantially equal to that shown in FIG. 6E, while the area shown in FIG. 6F is smaller than either of that in FIG. 6D or that in FIG. 6E. Based thereon, the data line parasitic capacitance Cdg according to the embodiments of the disclosure is kept unchanged or reduced in comparison with the prior art.

Sixthly, hereinafter, taking it as an example that the first electrode 10 comprises two strip arms 100 and one connecting arm 200 and the second electrode 20 comprises a strip arm 100, a comparison will be made for the TFTs in the prior art and according to an embodiment of the disclosure.

In the prior art, the width of channel W of the TFT shown in FIG. 1 may be approximately expressed by 2a+b, where a is the longitudinal length of the overlapped portion of the strip arm 100 of the second electrode 20 and the strip arms 100 of the first electrode 10 in the lateral direction as shown in FIG. 1, and b is the lateral length of the overlapped portion of the strip arm 100 of the second electrode 20 and the connecting arm 200 of the first electrode 10 in the longitudinal direction as shown in FIG. 1. In the embodiments as shown in FIGS. 2 and 3(a) of the disclosure, since the projection of the connecting arm 200 of the first electrode 10 on the gate 50 does not have an overlapped region with the gate 50, and the portion of the active layer 30 directly opposite the first region, which is the region between the connecting arm 200 of the first electrode 10 and the strip arm 100 of the second electrode 20, is partially hollowed-out, the width of channel of the TFT is 2a′. Here, though when the width of channel W is calculated according to the embodiment of the disclosure, the channel b between the connecting arm 200 of the first electrode 10 and the strip arm 100 of the second electrode 20 is not involved, the value of b in the width of channel W may be compensated for by appropriately increasing the length of the strip arms 100 of the first electrode 10, since the projection of the connecting arm 200 of the first electrode 10 on the gate 50 does not have an overlapped region with the gate 50. The embodiment of the disclosure is equivalent to the case where the value of W is not reduced. Since the value of b is small, the increased length of the strip arm 100 to compensate for W is small also, whereby the influence on transmission ratio may be negligible for consideration.

Exemplarily, take the product of 55UHD Dual Gate GOA as an example. In the prior art, the value for W/L of the TFT is usually set to be 22 μm/3.5 μm. The length of channel may typically take a value of 3.5-5 μm according to the current process capability, and the width for the first electrode 10 or the second electrode 20 of the TFT (i.e., the value of b) may typically take a value of 3.5-4 μm. For the product of 55UHD Dual Gate GOA, in order to reduce the overlapped capacitance of the TFT and the gate line, the value of b and the length of channel are both set as the minimum 3.5 μm according to the current process capability (due to discrepancies between different factories and facilities, b and the length of channel may have a value of 3.5 μm or so). Since W is 22 μm, a has a value of 9.25 μm, and in the embodiment of the disclosure, a′ may be designed to be 11 μm, such that even if there is not a channel b in the embodiment of the disclosure, the value of W may be compensated for by designing the value of a′ as 11 μm.

Based on the aforesaid description, referring to FIGS. 1 and 3(a) and taking as examples a TFT in the prior art with a of 9.25 μm and b of 3.5 μm and a TFT according to an embodiment of the disclosure with a′ of 11 μm, a comparison is made by computation for the gate line parasitic capacitance Cg, the source and gate parasitic capacitance Cgs and the drain and gate parasitic capacitance Cdg (all the parasitic capacitance is indicated by the overlapped area). The gate line parasitic capacitance Cg for TFT in the prior art is 409.6 μm², while the gate line parasitic capacitance Cg for TFT according to the embodiment of the disclosure is 345.2 μm². The source and gate parasitic capacitance Csg for TFT in the prior art is 112.0 μm², while the source and gate parasitic capacitance Csg for TFT according to the embodiment of the disclosure is 217.4 μm². The drain and gate parasitic capacitance Cdg for TFT in the prior art is 169.3 μm², while the drain and gate parasitic capacitance Cdg for TFT according to the embodiment of the disclosure is 60.3 μm². It can be seen that in comparison with the prior art, the gate line parasitic capacitance Cg according to the embodiment of the disclosure is substantially reduced. When the TFT according to the embodiment is shown in FIG. 3(a) with the number of the strip arm 100 of the second electrode 20 being less than that of the strip arms 100 of the first electrode 10 and the second electrode serving as the electrode for inputting signals, the drain and gate parasitic capacitance Cdg according to the embodiment of the disclosure is also substantially reduced in comparison with the prior art.

Moreover, those skilled in the art should appreciate that the capacitance has far more influence on the charging rate than the resistance.

With the TFT according to an embodiment of the disclosure, since the projection of the connecting arm 200 of the first electrode 10 on the gate 50 does not have an overlapped region with the gate 50 and the portion of the active layer 30 corresponding to the first region which is the region between the connecting arm 200 of the first electrode 10 and the strip arm 100 of the second electrode 20 is partially hollowed-out, the overlapped area between the projection of the active layer 30 on the gate 50 and the gate 50 is reduced, i.e., the gate line parasitic capacitance Cg is reduced. Meanwhile the data line parasitic capacitance Cd is kept unchanged or induced. Accordingly, the parasitic capacitance of the embodiment is reduced, thereby improving the charging rate of the TFT without increasing the transmission ratio of the displaying panel.

Based on the aforesaid description, since the embodiments of the disclosure can improve the charging rate of the TFTs, on the premise that the charging rate is satisfied, the length of the strip arms 100 can be appropriately reduced, i.e., the width of channel W is reduced, the aperture ratio is increased and the power loss of backlight is reduced.

Optionally, as shown in FIGS. 2 and 3(a), the first electrode 10 comprises two strip arms 100 and one connecting arm 200 which is connected with the ends of the two strip arms 100 to form a U-shaped structure. The second electrode 20 comprises one strip arm 100 which is positioned within the opening of the U-shaped structure.

FIGS. 2 and 3(a) show a TFT having a U-shaped TFT structure, i.e., the first electrode 10 surrounds the second electrode 20.

Here, the portion of the active layer 30 directly opposite the bottom of U-shaped structure is partially hollowed-out, and the overlapped area of the projection of the active layer 30 on the gate 50 and the gate 50 is reduced, that is to say, the gate line parasitic capacitance Cg is reduced.

Here, as shown in FIG. 2(a), the first electrode 10 is connected with the data line 70, and the second electrode 20 is connected through the via 60 with the pixel electrode 110. Alternatively, as shown in FIG. 3(a), the first electrode 10 is connected with the pixel electrode 110 through the via 60 and the second electrode 20 is connected with the data line 70.

Based thereon, it should be noted that if the second electrode 20 is connected with the data line 70 and the first electrode 10 is connected with the pixel electrode 110, the parasitic capacitance Cdg of the data line 70, when compared with the prior art, is reduced. If the second electrode 20 is connected with the pixel electrode 110 and the first electrode 10 is connected with the data line 70, the parasitic capacitance Cdg of the data line 70, when compared with the prior art, is not changed.

According to the embodiment of the disclosure, the first electrode 10 comprises two strip arms 100 and one connecting arm 200, forming a U-shaped structure. In the case where the second electrode 20 comprises one strip arm 100, since the portion of the active layer 30 directly opposite the bottom of U-shaped structure is partially hollowed-out, when compared with the prior art, in the embodiment of the disclosure, the overlapped area of the active layer 30 and the gate 50 is reduced, that is to say, the gate line parasitic capacitance Cg is reduced, while the parasitic capacitance Cdg of the data line 70 is not changed. Accordingly, the parasitic capacitance in the embodiment of the disclosure is reduced, thereby improving the charging rate of the TFT.

Alternatively, as shown in FIG. 4, the first electrode 10 comprises one connecting arm 200 and one strip arm 100. The connecting arm 200 and the strip arm 100 are connected with one another to form an L-shaped structure. The second electrode 20 comprises one strip arm 100 which is positioned within the opening of the L-shaped structure.

Here, the first electrode 10 may be connected with the data line 70, and the second electrode 20 may be connected through the via 60 with the pixel electrode 110 (not shown in the figure of the embodiment). Alternatively, as shown in FIG. 4, the first electrode 10 may be connected with the pixel electrode 110 through the via 60 and the second electrode 20 may be connected with the data line 70.

Based thereon, it should be noted that if the second electrode 20 is connected with the data line 70 and the first electrode 10 is connected with the pixel electrode 110, the parasitic capacitance Cdg of the data line 70, when compared with the prior art, is reduced. If the second electrode 20 is connected with the pixel electrode 110 and the first electrode 10 is connected with the data line 70, the parasitic capacitance Cdg of the data line 70, when compared with the prior art, is not changed.

Here, the second electrode 20 may comprise only one strip arm 100, alternatively may comprise one strip arm 100 and one connecting arm 200 which are connected with one another to form an L-shaped structure.

According to the embodiment of the disclosure, the first electrode 10 comprises one strip arm 100 and one connecting arm 200, forming an L-shaped structure. In the case where the second electrode 20 comprises one strip arm 100, since the portion of the active layer 30 directly opposite the bottom of the L-shaped structure is partially hollowed-out, when compared with the prior art, in the embodiment of the disclosure, the overlapped area of the active layer 30 and the gate 50 is reduced, that is to say, the gate line parasitic capacitance Cg is reduced, while the parasitic capacitance Cdg of the data line 70 is not changed, or reduced. Accordingly, the parasitic capacitance in the embodiment of the disclosure is reduced, thereby improving the charging rate of the TFT.

Based on the aforesaid description, it should be noted that the first electrode 10 of the TFT according to the embodiments of the disclosure is not limited to the aforesaid U- or L-shaped structure, but may alternatively have other shapes such as a turned flat “E”.

Preferably, as shown in FIG. 3(a), the number of the strip arm 100 of the second electrode 20 is less than that of the strip arm 100 of the first electrode 10 and the second electrode 20 is the electrode for inputting signals.

Here, the second electrode 20 is the electrode for inputting signals, i.e., the second electrode 20 is connected with the data line 70.

In the prior art, the number of the strip arm 100 of the second electrode 20 is less than that of the strip arm 100 of the first electrode 10 and the first electrode 10 is the electrode for inputting signals. The embodiment of the disclosure being compared with the prior art is equivalent to the case where the positions of the first electrode 10 and the second electrode 20 are swapped.

Here, the parasitic capacitance Cdg of the data line 70 is the overlapped area of the electrode connected with the data line 70 and the active layer 30. As shown in FIG. 3(a), when the first electrode 10 comprises two strip arms 100 and one connecting arm 200 while the second electrode 20 comprises one strip arm 100, referring to FIG. 6, the parasitic capacitance Cdg of the data line 70 of the TFT in the prior art as shown in FIG. 1 is shown in FIG. 6D, and the parasitic capacitance Cdg of the data line 70 of the TFT according to the embodiment as shown in FIG. 3(a) is shown in FIG. 6F. It can be seen from FIG. 6 that the area in FIG. 6F is less than that in FIG. 6D. Accordingly, according to the embodiment of the disclosure, as compared with the prior art, the overlapped area of the electrode connected with the data line 70 and the active layer 30 is substantially reduced, and thus the parasitic capacitance Cdg of the data line 70 is substantially reduced.

In the embodiment of the disclosure, since the number of the strip arm 100 of the second electrode 20 is less than that of the strip arms 100 of the first electrode 10 and the second electrode 20 is the electrode for inputting signals, parasitic capacitance Cdg of the data line 70, as compared with the prior art, is substantially reduced, thereby further improving the charging rate of the TFT.

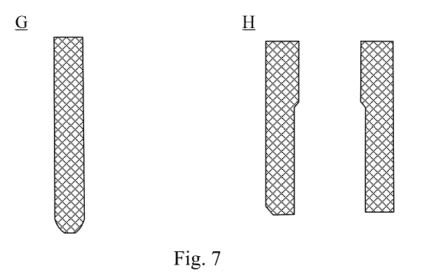

Based on the aforesaid description, it should be noted that when the number of the strip arm 100 of the second electrode 20 is less than that of the strip arms 100 of the first electrode 10 and the second electrode 20 is the electrode for inputting signals, the overlapped area of the electrode connected with the data line 70 and the gate 50 is reduced and the overlapped area of the electrode connected with the pixel electrode 110 and the gate 50 is increased, as compared with the prior art. Referring to FIG. 7, when the gate line is opened, the parasitic capacitance Cgs of the source (the electrode connected with the pixel electrode 110) and the gate 50 of the TFT in the prior art as shown in FIG. 1 is shown in FIG. 7G and the parasitic capacitance Cgs of the source and the gate 50 of the TFT according to the embodiment of the disclosure as shown in FIG. 3(a) is shown in FIG. 7H. It can be seen from FIG. 7 that the area in FIG. 7G is less than that in FIG. 7H. Accordingly, the parasitic capacitance Cgs of the source and the gate 50 according to the embodiment of the disclosure is increased as compared with the prior art.

The switching voltage Δvp for pixel is: Δvp=Cgs×(Vgh−Vgl)/(Cgs+Cst+Clc), where Δvp is switching voltage, Vgh is the voltage when the gate line is opened, Vgl is the voltage when the gate line is closed, Cst is storage capacitance, and Clc is liquid crystal capacitance. It can be known from the formula of the switching voltage Δvp for pixel that the parasitic capacitance Cgs of the source and the gate 50 may influence the switching voltage Δvp. However, for a displaying panel such as an ADS-type displaying panel or a HADS-type displaying panel), since Cst is large and typically of the order of pF while Cgs is of the order of fF, even increasing of the parasitic capacitance Cgs of the source and the gate 50 according to the embodiment of the disclosure does not have a substantial influence on Δvp, and does not influence the image quality.

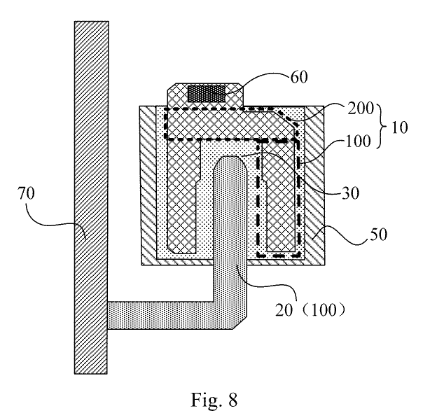

A TFT according to another embodiment of the disclosure, as shown in FIG. 8, comprises a first electrode 10 comprising a strip arm 100 and a connecting arm 200 connected with the strip arm 100, a second electrode 20 comprising a strip arm 100, an active layer 30, a gate 50, and a gate insulation layer. The strip arms 100 are arranged in a first direction which is perpendicular to the extending direction of the strip arms 100. Here, the number of the strip arm 100 of the second electrode 20 is less than that of the strip arm 100 of the first electrode 10, or the second electrode 20 does not comprise a connecting arm 200. The second electrode 20 is the electrode for inputting signals.

It should be noted that firstly, the second electrode 20 is the electrode for inputting signals, i.e., the second electrode 20 is connected with the data line 70.

Secondly, the second electrode 20 may either comprise or not comprise a connecting arm 200, to which there is no limitation. When the second electrode 20 does not comprise a connecting arm 200, then the second electrode 20 comprises only one strip arm 100.

Here, there is no limitation to the number of the strip arm 100 and the number of the connecting arm 200 included by the first electrode 10.

In the prior art, the number of the strip arm 100 of the second electrode 20 is less than that of the strip arm 100 of the first electrode 10 and the first electrode 10 is the electrode for inputting signals. The embodiment of the disclosure being compared with the prior art is equivalent to the case where the positions of the first electrode 10 and the second electrode 20 are swapped.

When the gate line is opened, the gate line parasitic capacitance Cg is the overlapped area of the source 30 and the gate 50. Now taking it as an example that the first electrode 10 comprises two connecting arms 200 and one strip arm 100 and the second electrode 20 comprises one strip arm 100, a comparison will be made between the TFT in the prior art and the TFT according to an embodiment of the disclosure. Referring to FIGS. 1 and 8, it can be seen that the gate line parasitic capacitance Cg in the prior at is substantially equal to that according to the embodiment of the disclosure.

The data line parasitic capacitance Cdg is the overlapped area of the electrode connected with the data line and the source 30. The first electrode 10 is the electrode for inputting signals in the prior art while the second electrode 20 is the electrode for inputting signals in the embodiment of the disclosure. Referring to FIGS. 1 and 8, it can be seen that the overlapped area of the electrode connected with the data line, i.e., the first electrode 10, and the source 30 in the TFT in the prior art as shown in FIG. 1 is larger than that of the electrode connected with the data line, i.e., the second electrode 20, and the source 30 in the TFT in the embodiment of the disclosure as shown in FIG. 8. Therefore, the data line parasitic capacitance Cdg according to the embodiment of the disclosure is substantially reduced as compared with the prior art.

Exemplarily, referring to FIGS. 1 and 8, the gate line parasitic capacitance Cg for TFT in the prior art is 409.6 μm², while the gate line parasitic capacitance Cg for TFT according to the embodiment of the disclosure is 396.7 μm². The source and gate parasitic capacitance Csg for TFT in the prior art is 112.0 μm², while the source and gate parasitic capacitance Csg for TFT according to the embodiment of the disclosure is 284.6 μm². The drain and gate parasitic capacitance Cdg for TFT in the prior art is 169.3 μm², while the drain and gate parasitic capacitance Cdg for TFT according to the embodiment of the disclosure is 54.2 μm². It can be seen that the drain and gate parasitic capacitance Cdg according to the embodiment of the disclosure is substantially reduced as compared with the prior art.

It should be noted that although the source and gate parasitic capacitance Cgs is increased according to the embodiment of the disclosure as compared with the prior art, the image quality is not influenced for the same reasons as set forth above and not repeated here.

In the TFT according to the embodiment of the disclosure, since the number of the strip arm 100 of the second electrode 20 is less than that of the strip arm 100 of the first electrode 10, or the second electrode 20 does not comprise a connecting arm 200, and the second electrode 20 is the electrode for inputting signals, the gate line parasitic capacitance Cg according to the embodiment of the disclosure is kept unchanged or reduced, and the data line parasitic capacitance Cdg is substantially reduced, whereby the charging rate for the TFT may be improved without increasing the transmission ratio of the displaying panel.

Preferably, as shown in FIG. 3(a), the projection of the connecting arm 200 of the first electrode 10 on the gate 50 does not have an overlapped area with the gate 50, and the portion of the orthogonal projection of the active layer 30 on the first electrode 10 or the second electrode 20 within the first region, which is the region between the connecting arm 200 and the strip arm 100 of the second electrode 20, is at least partially hollowed-out.

Here, the reason for at least partially hollowing-out is the same as set forth above and not repeated.

In the embodiment of the disclosure, the portion of the active layer 30 directly opposite the first region is partially hollowed-out, being equivalent to the case where the overlapped area of the source 30 and the gate 50 is reduced, i.e., the gate line parasitic capacitance is reduced, and thus the charging rate for the TFT is further improved.

Further preferably, as shown in FIGS. 8 and 3(a), the first electrode 10 comprises two strip arms 100 and one connecting arm 200 which is connected with the ends of the two strip arms 100 to form a U-shaped structure. The second electrode 20 comprises one strip arm 100 which is positioned within the opening of the U-shaped structure.

Here, the TFTs as shown in FIGS. 3(a) and 8 are of U-shaped TFT structure, i.e., the first electrode 10 surrounds the second electrode 20.

In the embodiments of the disclosure, since the first electrode 10 comprises two trip arms 100 and one connecting arm 200, the second electrode 20 comprises one strip arm 100, and the second electrode 20 is the electrode for inputting signals, in comparison with the prior, the overlapped area of the electrode for inputting signals and the active layer 30 is reduced, i.e., the data line parasitic capacitance Cdg is reduced, thereby improving the charging rate of the TFT.

In an embodiment of the disclosure there is provided an array substrate comprising a plurality of the aforesaid TFTs.

Here, when a portion of the orthogonal projection of the active layer 30 on the first electrode 10 or the second electrode 20 within the first region, which is the region between the connecting arm 200 and the strip arm 200 of the second electrode 20, is at least partially hollowed-out, according to a preferable embodiment of the disclosure, the first electrode 10 of the TFT is electrically connected with the pixel electrode 110 through the via 60, and the second electrode 20 is electrically connected with the data line; alternatively, the second electrode 20 of the TFT is electrically connected with the pixel electrode 110 through the via 60, and the first electrode 10 is electrically connected with the data line.

Based on the aforesaid description, since in comparison with the prior art, the overlapped area of the projection of the active layer 30 on the gate 50 and the gate 50 is reduced, i.e., the gate line parasitic capacitance Cg is reduced, while the data line parasitic capacitance Cdg is kept unchanged or reduced, the parasitic capacitance according to the embodiment of the disclosure is reduced, thereby improving the charging rate of the TFT.

When the number of the strip arm 100 of the second electrode 20 of the TFT is less than that of the strip arm 100 of the first electrode 10 or the second electrode 20 does not comprise a connecting arm 200, and the second electrode 20 is the electrode for inputting signals, according to a preferable embodiment of the disclosure, the first electrode 10 of the TFT is electrically connected with the pixel electrode 110 through the via 60, and the second electrode 10 is electrically connected with the data line.

Based on the aforesaid description, in comparison with the prior art, since the gate line parasitic capacitance Cg according to the embodiment of the disclosure is kept unchanged or reduced and the data line parasitic capacitance Cdg is substantially reduced, the parasitic capacitance according to the embodiment of the disclosure is reduced, thereby improving the charging rate of the TFT.

In an embodiment of the disclosure there is provided a displaying device comprising the aforesaid array substrate.

Here, the displaying device according to the embodiment of the disclosure may be any device which can display either moving (such as video) or stationary (such as static) image, or either text or picture image. More particularly, the embodiment is expected to be applied in or associated with various electronic devices, such as but not limited to mobile phones, wireless devices, personal digital assistants (PDAs), hand-held or portable computers, GPS receivers/navigators, cameras, MP4 video players, video cameras, game consoles, watches, clocks, TV monitors, flat-panel displays, computer monitors, vehicle displays such as odometer displays, navigators, cabin controller and/or displays, camera view displays such as a displays for a rear view camera of a vehicle, electronic pictures, electronic advertising boards and indicators, projectors, building structures, packages and aesthetic structures such as a display for treasure image, and the like. In addition, the displaying device may alternatively be a displaying panel.

Since the displaying device according to the embodiment of the disclosure comprises the aforesaid array substrate which has decreased parasitic capacitance, the charging rate of the TFT can be improved.

According to an embodiment of the disclosure, there is provided a method preparing a TFT comprising:

as shown in FIG. 3(a), forming. on a base substrate 80, a gate 50, a gate insulation layer 90, an active layer 30, a first electrode 10 and a second electrode 20, wherein the first electrode 10 comprises a strip arm 100 and a connecting arm 200 connected with the strip arm 100, the second electrode 20 comprises a strip arm 100, the strip arms 100 are arranged sequentially in the first direction which is perpendicular to the extending direction of the strip arms, the projection of the connecting arm 200 of the first electrode 10 on the gate 50 does not have an overlapped region with the gate 50, the region between the connecting arm 200 and the strip arm 100 of the second electrode 20 is the first region, and the portion of the active layer 30 directly opposite the first region is partially hollowed-out.

Here, the gate 50 may be firstly formed, then the insulation layer 90, and finally the active layer 30, the first electrode 10 and the second electrode 20. Alternatively, the active layer 30, the first electrode 10 and the second electrode 20 may be firstly formed, then the insulation layer 90, and finally the gate 50.

It should be noted that according to an embodiment of the disclosure, the date line 70 may be formed at the same time as the first and second electrode 10 and 20 is formed.

According to the method for preparing a TFT of the embodiment of the disclosure, since the projection of the connecting arm 200 of the first electrode 10 on the gate 50 does not have an overlapped region with the gate 50 and the portion of the active layer 30 corresponding to the first region, which is the region between the connection arm 200 of the first electrode 10 and the strip arm 100 of the second electrode 20, is partially hollowed-out, the overlapped area of the projection of the active layer 30 on the gate 50 and the gate 50 is reduced, i.e., the gate line parasitic capacitance Cg is reduced, while the data line parasitic capacitance Cdg is kept unchanged or reduced, accordingly the parasitic capacitance according to the embodiment of the disclosure is reduced, thereby improving the charging rate of the TFT without increasing the transmission ratio of the displaying panel.

Preferably, forming on the base substrate 80 the active layer 30, the first electrode 10 and the second electrode 20 comprises:

S100: forming on the base substrate 80 a thin film for active layer,

wherein there is no limitation to materials for the thin film for active layer, which may be an amorphous silicon layer or a polycrystalline silicon layer and the like;

S101: forming on the thin film for active layer a conductive thin film,

wherein there is no limitation to materials for the conductive thin film, which may at least one of elementary substance such as Ag, Al, Mg and Cu and alloys thereof;

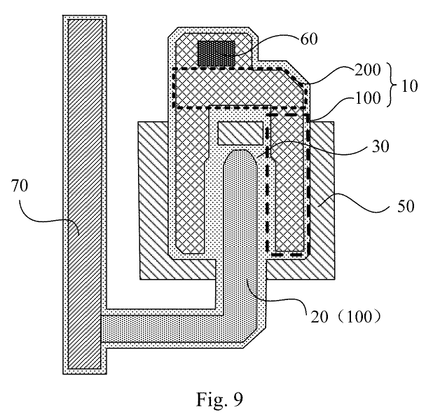

S102: as shown in FIG. 9, using a half-tone mask to simultaneously mask and expose the thin film for active layer and the conductive thin film, and using single one etching process to form the active layer 30 and the first and second electrode 10 and 20,

wherein there is no limitation to the type of the mask which may be, for example, a half tone mask (HTM), or a single slit mask (SSM), or a modified single slit mask (MSM).

According to the embodiment of the disclosure, as compared with the use of two masks to form the active layer 30 and the first and second electrode 10 and 20, respectively, using the half-tone mask to simultaneously the active layer 30 and the first and second electrode 10 and 20 with single one patterning process saves a mask process and reduces the production cost.

According to another embodiment of the disclosure, a method for preparing a TFT comprises a first electrode 10 comprising a strip arm 100 and a connecting arm 200 connected with the strip arm 100, a second electrode 20 comprising a strip arm 100, an active layer 30, a gate 50, and a gate insulation layer. The strip arms 100 are arranged sequentially in a first direction which is perpendicular to the extending direction of the strip arms 100. Here, as shown in FIGS. 3(a) and 8, the number of the strip arm 100 of the second electrode 20 is less than that of the strip arm of the first electrode 10 or the second electrode 20 does not comprise a connecting arm 220, and the second electrode 20 is the electrode for inputting signals.

It should be noted that according to the embodiment of the disclosure, the data line 70 may be formed at the same time when the first and second electrode 10 and 20 is formed.

Based on the aforesaid description, according to the embodiment of the disclosure, the active layer 30 and the first and second electrode 10 and 20 are simultaneously formed with single one patterning process, a particular process of which is the same as the aforesaid steps of S100-S102 and not repeated here.

According to the method of preparing a TFT of the embodiment of the disclosure, since the number of the strip arm 100 of the second electrode 20 is less than that of the strip arm of the first electrode 10 or the second electrode 20 does not comprise a connecting arm 200, and the second electrode 20 is the electrode for inputting signals, in comparison with the prior art, the gate line parasitic capacitance Cg according to the embodiment of the disclosure is kept unchanged or reduced, and the data line parasitic capacitance Cdg is substantially reduced, thereby improving the charging rate of the TFT.

The aforesaid description only involves particular embodiments of the disclosure, and the protection scope of the disclosure is not limited thereto. It is apparent for those skilled in the art that any modification or replacement within the disclosure should be encompassed within the protection scope of the disclosure which should by defined by the appended claims.

What is claimed is:

1. A thin film transistor comprising a first electrode, a second electrode, an active layer, a gate and a gate insulation layer,
wherein the first electrode comprises a strip arm and a connecting arm connected with the strip arm, the second electrode comprises a strip arm, the strip arm of the first electrode and the strip arm of the second electrode are arranged sequentially in a first direction which is perpendicular to the extending direction of the strip arm of the first electrode and the strip arm of the second electrode; and
wherein a projection of the connecting arm of the first electrode on the gate does not have an overlapped region with the gate, and a portion of an orthogonal projection of the active layer on the first electrode or the second electrode within a first region, which is a region between the connecting arm and the strip arm of the second electrode, is at least partially hollowed-out.

2. The thin film transistor according to claim 1, wherein the first electrode comprises two said strip arms and one said connecting arm, wherein the connecting arm is connected with ends of the two strip arms to form a U-shaped structure, and
wherein the second electrode comprises one said strip arm which is positioned within an opening of the U-shaped structure.

3. The thin film transistor according to claim 1, wherein the first electrode comprises one said connecting arm and one said strip arm, wherein the connecting arm and the strip arm are connected with one another to form a L-shaped structure, and
wherein the second electrode comprises one said strip arm which is positioned within an opening of the L-shaped structure.

4. The thin film transistor according to claim 1, wherein a number of the strip arm of the second electrode is less than a number of the strip arm of the first electrode, and
wherein the second electrode is an electrode for inputting signals.

5. A thin film transistor comprising a first electrode, a second electrode, an active layer, a gate and a gate insulation layer,
wherein the first electrode comprises a strip arm and a connecting arm connected with the strip arm, the second electrode comprises a strip arm, the strip arm of the first electrode and the strip arm of the second electrode are arranged sequentially in a first direction which is perpendicular to the extending direction of the strip arm of the first electrode and the strip arm of the second electrode; and
wherein a number of the strip arm of the second electrode is less than a number of the strip arm of the first electrode or the second electrode does not comprise the connecting arm, wherein the second electrode is an electrode for inputting signals.

6. The thin film transistor according to claim 5, wherein a projection of the connecting arm of the first electrode on the gate does not have an overlapped region with the gate, and a portion of an orthogonal projection of the active layer on the first electrode or the second electrode within a first region, which is a region between the connecting arm and the strip arm of the second electrode, is at least partially hollowed-out.

7. The thin film transistor according to claim 5, wherein the first electrode comprises two said strip arms and one said connecting arm, wherein the connecting arm is connected with ends of the two strip arms to form a U-shaped structure, and
wherein the second electrode comprises one said strip arm which is positioned within an opening of the U-shaped structure.

8. An array substrate comprising a plurality of thin film transistors according to claim 1.

9. The array substrate according to claim 8, wherein the first electrode of the thin film transistor is electrically connected with a pixel electrode through a via, and the second electrode is electrically connected with a data line, or
wherein the second electrode of the thin film transistor is electrically connected with a pixel electrode through a via, and the first electrode is electrically connected with a data line.

10. An array substrate comprising a plurality of thin film transistors according to claim 5.

11. The array substrate according to claim 10, wherein the first electrode of the thin film transistor is electrically connected with a pixel electrode through a via, and the second electrode is electrically connected with a data line.

12. A displaying device comprising an array substrate according to claim 8.

13. A displaying device comprising an array substrate according to claim 10.

14. A method for preparing a thin film transistor comprising:
forming, on a base substrate, a gate, a gate insulation layer, an active layer, a first electrode and a second electrode, wherein the first electrode comprises a strip arm and a connecting arm connected with the strip arm, the second electrode comprises a strip arm, the strip arm of the first electrode and the strip arm of the second electrode are arranged sequentially in a first direction which is perpendicular to the extending direction of the strip arm of the first electrode and the strip arm of the second electrode, and wherein a projection of the connecting arm of the first electrode on the gate does not have an overlapped region with the gate, and a portion of the active layer directly opposite a first region, which is a region between the connecting arm and the strip arm of the second electrode, is at least partially hollowed-out.

15. The method for preparing a thin film transistor according to claim 14, wherein the step of forming, on the base substrate, the active layer, the first electrode and the second electrode comprises:
forming a thin film for active layer on the base substrate,
forming a conductive thin film on the thin film for active layer,
using a half-tone mask to simultaneously mask and expose the thin film for active layer and the conductive thin film, and
using one etching process to form the active layer, the first electrode and the second electrode.
